(19) United States
(12) Patent Application Publication
(10) Pub. No.: US 2024/0096397 A1
(43) Pub. Date: Mar. 21, 2024

(54) DATA SAMPLING CIRCUIT, DELAY DETECTION CIRCUIT AND MEMORY

(71) Applicant: CHANGXIN MEMORY TECHNOLOGIES, INC., Hefei City (CN)

(72) Inventor: Zhiqiang ZHANG, Hefei City (CN)

(73) Assignee: CHANGXIN MEMORY TECHNOLOGIES, INC., Hefei City (CN)

(21) Appl. No.: 18/527,249

(22) Filed: Dec. 2, 2023

Related U.S. Application Data
(63) Continuation of application No. PCT/CN2023/073884, filed on Jan. 30, 2023.

(30) Foreign Application Priority Data
Sep. 21, 2022 (CN) 202211152118.7

(51) Int. Cl. G11C 11/4076; G11C 11/4096; H03L 7/099

(52) U.S. Cl. CPC G11C 11/4076; G11C 11/4096; H03L 7/0995

(57) ABSTRACT

A data sampling circuit includes a first signal path and a second signal path. The first signal path is arranged to receive a first signal, process and transmit the first signal. The first signal path has a first delay, and the first delay includes a first physical delay and a compensation delay. The second signal path is arranged to receive a second signal, receive processed first signal from the first signal path, and sample the second signal according to the processed first signal.

### CROSS-REFERENCE TO RELATED APPLICATIONS

This is a continuation of International Patent Application No. PCT/CN2023/073884 filed on Jan. 30, 2023, which claims priority to Chinese Patent Application No. 202211152118.7 filed on Sep. 21, 2022. The disclosures of the above-referenced applications are hereby incorporated by reference in their entirety.

### BACKGROUND

With the development of integrated circuit technology, a chip frequency of a chip needs to be higher and higher to improve the operating speed of the chip. However, with the increase of the chip frequency, timing of signals in the chip will become more difficult to control, which may affect the normal operation of the chip.

### SUMMARY

In view of this, embodiments of the present disclosure provides a data sampling circuit, a delay detection circuit and a memory, which can keep the relative delay of a first signal and a second signal stable and avoid sampling failure.

The technical solutions of embodiments of the present disclosure may be implemented as follows.

The embodiments of the present disclosure provide a data sampling circuit, including a first signal path and a second signal path. The first signal path is arranged to receive a first signal, process and transmit the first signal. The first signal path has a first delay, and the first delay includes a first physical delay and a compensation delay. The second signal path is arranged to receive a second signal, receive the processed first signal from the first signal path, and sample the second signal according to the processed first signal.

The embodiments of the present disclosure also provide a delay detection circuit, including: a simulation unit and a counter unit. The simulation unit is arranged to simulate a first delay of a first signal path and generate a delay to be measured. The first delay includes a first physical delay and a compensation delay. The counter unit is coupled to the simulation unit and is arranged to count the at least one parameter to be measured corresponding to the simulation unit to calculate a delay amount of the delay to be measured.

The embodiment of the present disclosure also provides a memory, including at least one of: the data sampling circuit as described in the above solution, or the delay detection circuit as described in the above solution.

It can be seen that the embodiments of the present disclosure provide a data sampling circuit, a delay detection circuit and a memory. The data sampling circuit includes a first signal path and a second signal path. The first signal path is arranged to receive a first signal, process and transmit the first signal. The first signal path has a first delay, and the first delay includes a first physical delay and a compensation delay. The second signal path is arranged to receive a second signal, receive processed first signal from the first signal path, and sample the second signal according to the processed first signal. Thus, when the first physical delay changes due to the influence of the PVT condition, the compensation delay provides a corresponding compensation to reduce the change of the first delay caused due to the influence of the PVT condition. Therefore, the relative delay between the first signal and the second signal can be kept stable, thereby avoid the sampling failure.

### BRIEF DESCRIPTION OF THE DRAWINGS

FIG. 1 is schematic structure diagram one of a data sampling circuit provided by an embodiment of the present disclosure;

FIG. 2 is schematic structure diagram two of a data sampling circuit provided by an embodiment of the present disclosure;

FIG. 3 is schematic structure diagram three of a data sampling circuit provided by an embodiment of the present disclosure;

FIG. 4 is schematic structure diagram four of a data sampling circuit provided by an embodiment of the present disclosure;

FIG. 5 is schematic structure diagram five of a data sampling circuit provided by an embodiment of the present disclosure;

FIG. 6 is schematic structure diagram six of a data sampling circuit provided by an embodiment of the present disclosure;

FIG. 7 is schematic structure diagram one of a delay detection circuit provided by an embodiment of the present disclosure;

FIG. 8 is schematic structure diagram two of a delay detection circuit provided by an embodiment of the present disclosure;

FIG. 9 is schematic structure diagram three of a delay detection circuit provided by an embodiment of the present disclosure; and

FIG. 10 is a schematic structure diagram of a memory provided by an embodiment of the present disclosure.

### DETAILED DESCRIPTION

In order to make the purposes, technical solutions and advantages of the present disclosure clearer, the technical solutions of the disclosure will further be described below in combination with the drawings and the embodiments of the disclosure in detail. The described embodiments should not be considered as limits to the disclosure. All other embodiments obtained by those of ordinary skill in the art without creative work shall fall within the scope of protection of the disclosure.

In the following description, “some embodiments” involved describes a subset of all possible embodiments, but it is to be understood that “some embodiments” may be a same subset or different subsets of all possible embodiments and may be combined with each other without conflict.

If a similar expression “first/second” used in the disclosure, the following description is added. In the following description, the term “first/second/third” involved is merely used to distinguish similar objects without representing a specific order for the objects. It is to be understood that “first/second/third” may be interchanged to specific sequences or orders if allowed to implement the embodiments of the disclosure described herein in sequences except the illustrated or described ones.

Unless otherwise defined, all technical and scientific terms used herein have the same meanings as those are commonly understood by those skilled in the art of the present disclosure. The terms used herein are only adopted to describe the embodiments of the disclosure and not intended to limit the disclosure.

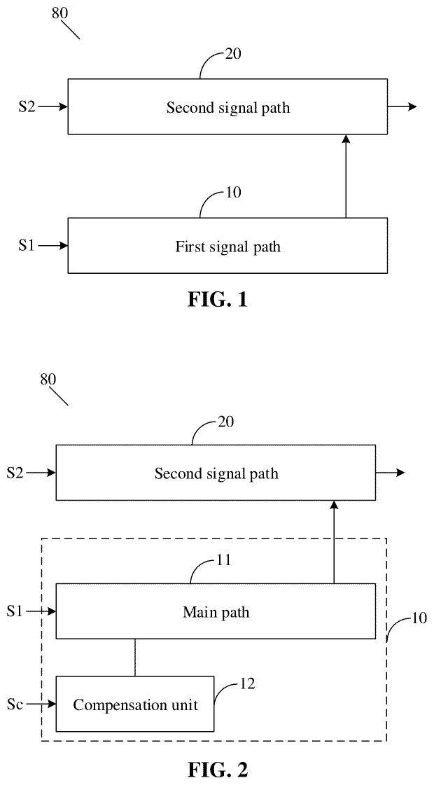

FIG. 1 is an optional schematic structure diagram of a data sampling circuit provided by an embodiment of the present disclosure. As shown in FIG. 1, the data sampling circuit 80 includes a first signal path 10 and a second signal path 20. The first signal path 10 is arranged to receive a first signal S1, process and transmit the first signal S1. Here, the first signal path 10 has a first delay, and the first delay includes a first physical delay and a compensation delay. The second signal path 20 is arranged to receive a second signal S2, receive processed first signal S1 from the first signal path 10, and sample the second signal S2 according to the processed first signal S1.

It should be noted that a signal may be delayed due to a physical delay of the signal path during transmission. The physical delay includes a route path delay and a circuit delay, in which the route path delay is positively correlated with the length of the route path in the signal path, and the circuit delay is positively correlated with the number of gate level circuits in the signal path. Among the physical delay, the circuit delay is more sensitive than the route path delay and more susceptible to a process voltage temperature (PVT) condition. Therefore, the first physical delay of the first signal path 10 may change due to the influence of the PVT condition, which in turn may affect the relative delay between the first signal S1 and the second signal S2.

It should also be noted that the PVT condition includes a process condition, a voltage condition and a temperature condition. Due to the process variation in the chip manufacturing process, such as different doping concentrations, diffusion depths and etching degrees, the process conditions for different chips may be different. Different process conditions may be represented as different process corners, such as a fast corner, a typical corner and a worst corner, etc. Meanwhile, the voltage environment and temperature environment in which the chip works are represented by the voltage condition and the temperature condition respectively. Since the data sampling circuit 80 is integrated into the chip, the PVT condition corresponding to the chip is the PVT condition corresponding to the data sampling circuit 80.

In the embodiments of the present disclosure, the second signal path 20 samples the second signal S2 according to the processed first signal S1, that is, the processed first signal S1 serves as a sampling clock signal of the second signal S2. Therefore, the relative delay between the first signal S1 and the second signal S2 needs to be kept stable to avoid sampling failure.

In the embodiments of the present disclosure, the first delay includes the first physical delay and the compensation delay. When the first physical delay changes due to the influence of the PVT condition, the compensation delay may provide a corresponding compensation to reduce the change of the first delay due to the influence of the PVT condition, such that the relative delay between the first signal S1 and the second signal S2 can be kept stable, thereby avoiding the sampling failure.

In some embodiments of the present disclosure, as shown in FIG. 2, the first signal path 10 includes a main path 11 and a compensation unit 12. The main path 11 is arranged to process and transmit the first signal S1. The main path 11 has the first physical delay. The compensation unit 12 is coupled to the main path 11. The compensation unit 12 is arranged to receive at least one compensation signal Sc from a compensation controller, and generate the compensation delay in response to the at least one compensation signal Sc. Herein, the at least one compensation signal Sc is obtained according to the PVT condition.

It should be noted that the coupling described in the present disclosure includes a direct electrical connection or an indirect electrical connection through an electrical element, which will not be repeated below.

In the embodiments of the present disclosure, the compensation controller generates the compensation signal Sc according to the PVT condition corresponding to the data sampling circuit 80, that is, the compensation controller may generate the compensation signal Sc according to at least one of a process condition, a voltage condition or a temperature condition. In the PVT condition, the process condition may be determined during the chip manufacturing process, and the voltage condition and temperature condition may be obtained through measuring by the compensation controller in real time.

It is to be understood that since the compensation signal Sc is generated according to the PVT condition corresponding to the data sampling circuit 80, the compensation unit 12 generates the compensation delay according to the compensation signal Sc, which may compensate the change of the first physical delay due to the influence of the PVT condition. Therefore, the relative delay between the first signal S1 and the second signal S2 can be kept stable, thereby avoiding the sampling failure.

In some embodiments of the present disclosure, the compensation controller includes a temperature sensor. The at least one compensation signal includes at least one temperature compensation signal. The at least one temperature compensation signal is obtained by the temperature sensor according to the temperature condition.

In the embodiments of the present disclosure, the temperature sensor may measure the real-time temperature of the chip in the working state, and determine the at least one temperature compensation signal corresponding to the real-time temperature according to the change curve of the first physical delay with the temperature, and then transmit the at least one temperature compensation signal to the compensation unit.

It can be understood that the temperature sensor obtains the at least one temperature compensation signal according to the temperature condition, and further, the at least one temperature compensation signal may be used to control the compensation unit to generate a compensation delay to compensate for the change of the first physical delay due to the influence of the temperature condition. Therefore, the relative delay between the first signal and the second signal can be kept stable, thereby avoiding the sampling failure.

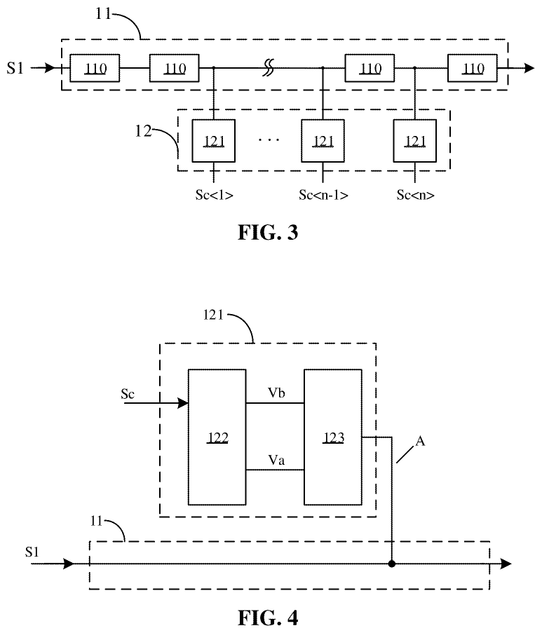

In some embodiments of the present disclosure, as shown in FIG. 3, the compensation unit 12 includes at least one first load capacitor 121. A load connecting end of the at least one first load capacitor 121 is connected to any position of the main path 11. The at least one first load capacitor 121 is arranged to receive the at least one compensation signal Sc respectively, be activated by triggering of the at least one compensation signal Sc<1>˜Sc<n> and change a capacitance (capacitance value), to generate the compensation delay.

In the embodiments of the present disclosure, referring to FIG. 3, the main path 11 includes a plurality of circuit modules 110. The circuit modules 110 have different functions for processing and transmitting the first signal S1. These circuit modules 110 generate physical delays and the sum of the physical delays generated by all circuit modules 110 is the first physical delay.

Meanwhile, the compensation unit 12 includes at least one first load capacitor 121. A load connecting end of the at least one first load capacitor 121 is connected to any position of the main path 11. After each first load capacitor 121 is activated, the capacitance of the first load capacitor 121 may change, resulting in a certain load delay. The sum of the load delays generated by all the first load capacitors 121 is the compensation delay.

It should be noted that the load delays generated by the first load capacitors 121 may be the same or different. Since a load delay generated by the first load capacitor 121 is related to an equivalent device size of the first load capacitor 121, the equivalent device sizes of the first load capacitors 121 may be the same or different. The device size may be the channel aspect ratio of the transistor corresponding to the first load capacitors 121. For example, the ratio of equivalent device sizes of the first load capacitors 121 may be 1:1:1 . . . :1 or 1:2:4 . . . :2ⁿ⁻¹, where the latter can provide a larger adjustment range of compensation delay than the former.

In the embodiments of the present disclosure, the at least one first load capacitor 121 may receive the at least one compensation signal Sc<1>˜Sc<n> respectively. Each first load capacitor 121 may be activated by the triggering of a corresponding compensation signal, and correspondingly, the first load capacitor 121 may also stop being activated by the triggering of the corresponding compensation signal. The two triggering conditions correspond to two different levels of the compensation signal. Each first load capacitor 121 generates a corresponding load delay when the first load capacitor 121 is in an active state and does not generate the corresponding load delay when the first load capacitor 121 is in a deactivated state.

For example, a high level (i.e., “1”) of each compensation signal triggers the corresponding first load capacitor 121 to be activated, and a low level (i.e., “0”) of each compensation signal triggers the corresponding first load capacitor 121 to stop being activated. Thus, if the compensation signals Sc<1>, Sc<n−1> and Sc<n> are 1, 0 and 1, respectively, then the first and nth first load capacitors 121 are activated by the triggering, while the (n−1)th first load capacitor 121 stops being activated by the triggering. In such case, the compensation delay includes the load delays generated by the first and nth first load capacitors 121, but does not include the load delay generated by the (n−1)th first load capacitor 121.

It is to be understood that the load delay generated by the at least one first load capacitor 121 may be controlled by the at least one compensation signal Sc<1>˜Sc<n>, and thus the compensation delay generated by the compensation unit 12 may be controlled. Therefore, the change of the first physical delay of the main path 11 due to the influence of the PVT condition can be compensated, so as to keep the relative delay between the first signal S1 and the second signal S2 stable and avoid the sampling failure.

In some embodiments of the present disclosure, as shown in FIG. 4, each first load capacitor 121 includes an input subunit 122 and a capacitor subunit 123. The input subunit is arranged to receive the compensation signal Sc and generate two control signals Va and Vb based on the compensation signal Sc. The capacitor subunit 123 is connected to the input subunit 122 and is arranged to be activated by the triggering of the two control signals Va and Vb, and change the capacitance of the first load capacitor 121. An end A of the capacitor subunit 123 serves as the load connecting end of the first load capacitor 121 and is connected to any position on the main path 11.

In some embodiments of the present disclosure, as shown in FIG. 5, the input subunit 122 includes a first inverter 124 and a second inverter 125. The first inverter 124 is arranged to receive the compensation signal Sc and output a first control signal Va of the two control signals. The input end of the second inverter 125 is connected to the output end of the first inverter 124. The second inverter 125 is arranged to output a second control signal Vb of the two control signals.

The capacitor subunit 123 includes a first metal oxide semiconductor (MOS) transistor 126 and a second MOS transistor 127. Both the source and drain of the first MOS transistor 126 are connected to the output end of the first inverter. Both the source and drain of the second MOS transistor 127 are connected to the output end of the second inverter 125. The gate of the second MOS transistor 127 and the gate of the first MOS transistor 126 are connected and both serve as the load connecting end A of the first load capacitor 121. The type of the second MOS transistor 127 is opposite to that of the first MOS transistor 126.

In the embodiments of the present disclosure, the first MOS transistor 126 and the second MOS transistor 127 are MOS transistors of opposite types, for example, the first MOS transistor 126 is an N-channel MOS (NMOS) transistor and the second MOS transistor 127 is a P-channel MOS (PMOS) transistor. After the compensation signal Sc passes through the first inverter 124 and the second inverter 125, the first control signal Va and the second control signal Vb are obtained, and the levels of the first control signal Va and the second control signal Vb are opposite, therefore the first MOS transistor 126 and the second MOS transistor 127 can be turned on simultaneously.

In the embodiments of the present disclosure, taking the first MOS transistor 126 being an NMOS transistor, and the second MOS transistor 127 being a PMOS transistor as an example. When the first load capacitor 121 receives the compensation signal Sc having a high level, after the compensation signal Sc passes through the first inverter 124 and the second inverter 125, the first control signal Va having a low level and the second control signal Vb having a high level are obtained. Further, the first MOS transistor 126 is turned on by the triggering of the first control signal Va, and the gate capacitance of the first MOS transistor 126 is changed. The second MOS transistor 127 is turned on by the triggering of the second control signal Vb, and the gate capacitance of the second MOS transistor 127 is changed. Thus, the capacitance of the first load capacitor 121 is changed, and the delay on the main path is affected, that is, the first delay is compensated.

It is to be understood that two MOS transistors of opposite types are used to form a capacitor unit, and further, two inverters are used to provide different levels to the two MOS transistors respectively, so as to change the conduction state of the two MOS transistors and change the capacitance of the first load capacitor to compensate for the first delay. In this way, the change of the first physical delay of the main path due to the influence of the PVT condition can be compensated, so as to keep the relative delay between the first signal and the second signal stable and avoid the sampling failure.

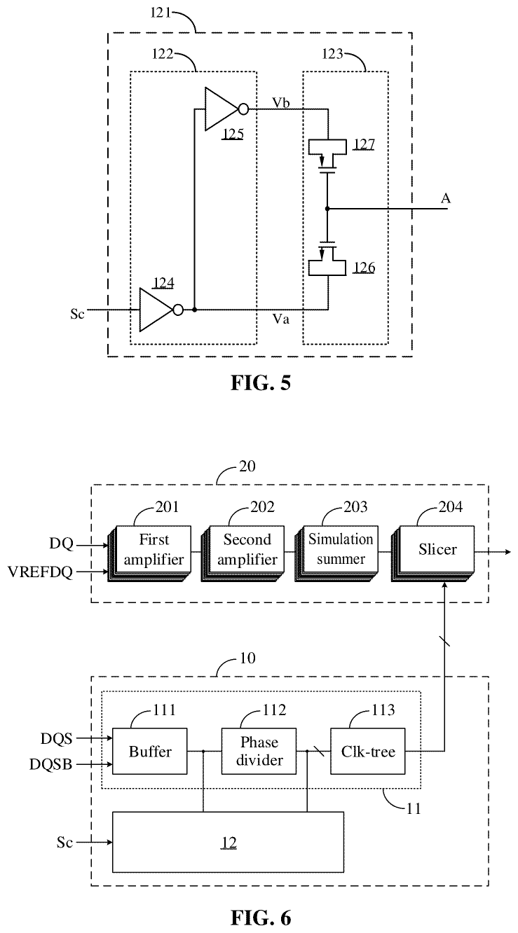

In some embodiments of the present disclosure, as shown in FIG. 6, the first signal is a data strobe signal DQS and the second signal is a data signal DQ. The main path 11 of the first signal path 10 includes: a buffer 111, a phase divider 112, and a clk-tree (clock tree) 113. The buffer 111, the phase divider 112, and the clk-tree 113 are sequentially coupled to each other. The second signal path 20 includes: a first amplifier 201, a second amplifier 202, a simulation summer 203, and a slicer (sampler) 204. The first amplifier 201, the second amplifier 202, the simulation summer 203, and the slicer 204 are sequentially coupled to each other.

In the embodiments of the present disclosure, referring to FIG. 6, the buffer 111 is arranged to receive the data strobe signal DQS and a complementary data strobe signal DQSB, amplify and drive the data strobe signal DQS and the complementary data strobe signal DQSB to avoid signal strength attenuation. The phase divider 112 is arranged to perform phase splitting on the data strobe signal DQS and the complementary data strobe signal DQSB to obtain a plurality of data strobe sub-signals having equal phase differences to achieve frequency reduction of the data strobe signal DQS. The clk-tree 113 is arranged to drive the plurality of data strobe sub-signals to avoid signal strength attenuation and to transmit the plurality of data strobe sub-signals to the slicer 204.

In the embodiments of the present disclosure, referring to FIG. 6, the first amplifier 201 receives the data signal DQ and a reference data signal VREFDQ. The first amplifier 201 and the second amplifier 202 are arranged to amplify the data signal DQ. The simulation summer 203 is arranged to receive the amplified data signal DQ and perform decision feedback equalization processing on the amplified data signal DQ to eliminate interSymbol interference (ISI). The slicer 204 is arranged to receive the data signal DQ after the decision feedback equalization processing and the plurality of data strobe sub-signals, and sample the data signal DQ according to the plurality of data strobe sub-signals.

In the embodiments of the present disclosure, referring to FIG. 6, the difference between the first physical delay of the main path 11 of the first signal path 10 and the second physical delay of the second signal path 20 is denoted as TDQS2DQ. When a signal transmitter transmits the data strobe signal DQS and the data signal DQ, a certain relative delay is imposed to the transmission time of the two signals according to TDQS2DQ, that is, a mismatch delay is imposed between the data strobe signal DQS and the data signal DQ, for example, the data strobe signal DQS is transmitted first, and then the data signal DQ is transmitted. Thus, the difference between the physical delays on the two signal paths can be compensated, so that the timing of the data strobe signal DQS and the data signal DQ can be matched during the sampling process, so as to complete the sampling process.

However, the main path 11 of the first signal path 10 is susceptible to the PVT condition, resulting in the first physical delay being changed. Therefore, TDQS2DQ will also change greatly due to the influence of the PVT condition. Further, if TDQS2DQ increases, the signal transmitter also needs to increase the mismatch delay imposed between the data strobe signal DQS and the data signal DQ when transmitting the data strobe signal DQS and the data signal DQ. This will bring more burden to the signal transmitter, and even exceed the adjustment range of the signal transmitter to the mismatch delay, resulting in an invalid mismatch delay.

Continuing referring to FIG. 6, the compensation unit 12 generates the compensation delay based on the compensation signal Sc, which is obtained according to the PVT condition, that is, the compensation unit 12 may generate the compensation delay according to the PVT condition. Meanwhile, the mismatch delay is obtained according to the difference between the total delay of the first signal path and the total delay of the second signal path. The total delay of the first signal path is the first delay, and the first delay includes the first physical delay and the compensation delay; and the total delay of the second signal path is the second physical delay. Therefore, the compensation delay may compensate for the change of the mismatch delay due to the influence of the PVT condition, thereby reducing the mismatch delay between the data strobe signal DQS and the data signal DQ imposed by the signal transmitter, so that the mismatch delay is controlled within a certain range. Thus, it is ensured that timing of the data strobe signal DQS and the data signal DQ is effectively controlled, thereby ensuring that the sampling of the data signal DQ can be effectively performed.

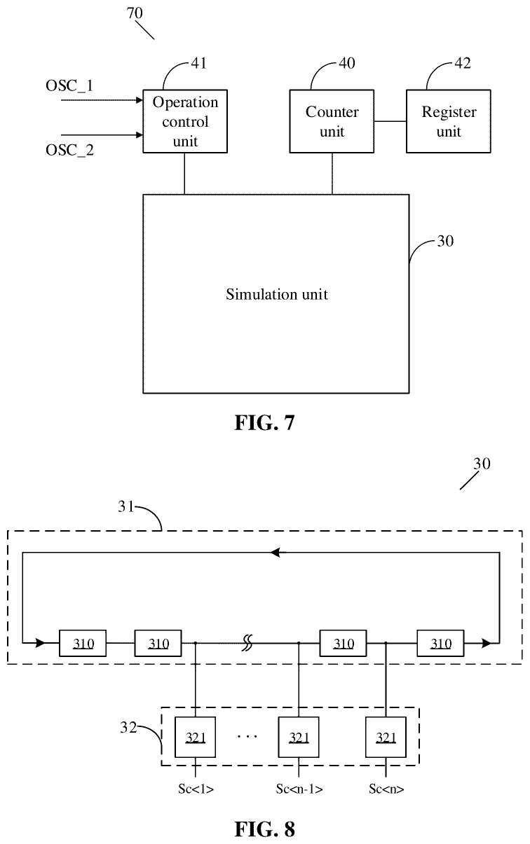

FIG. 7 is an optional schematic structure diagram of a delay detection circuit provided by an embodiment of the present disclosure. As shown in FIG. 7, the delay detection circuit 70 includes a simulation unit 30 and a counter unit 40. The simulation unit 30 is arranged to simulate a first delay of a first signal path and generate a delay to be measured. Here, the first delay includes a first physical delay and a compensation delay. The counter unit 40 is coupled to the simulation unit 30, and is arranged to count at least one parameter to be measured corresponding to the simulation unit 30 to calculate a delay amount of the delay to be measured.

In the embodiments of the present disclosure, since the first delay of the first signal path is not easy to measure, the first delay may be simulated by the simulation unit 30 to generate the delay to be measured, and then the delay amount of the first delay can be determined by calculating the delay amount of the delay to be measured.

Meanwhile, the first delay includes the first physical delay and the compensation delay. When the first physical delay changes due to the influence of the PVT condition, the compensation delay provides a corresponding compensation to reduce the change of the first delay caused due to the influence of the PVT condition. Correspondingly, the simulation unit 30 may simulate the first physical delay and the compensation delay respectively to obtain the delay to be measured.

In some embodiments of the present disclosure, as shown in FIG. 7, the delay detection circuit 70 further includes an operation control unit 41 and a register unit 42. The operation control unit 41 is coupled to the simulation unit 30, and is arranged to receive a start signal OSC_1 and a stop signal OSC_2, and control an operation time of the simulation unit 30 according to the start signal OSC_1 and the stop signal OSC_2. The register unit 42 is coupled to the counter unit 40, and is arranged to register the at least one parameter to be measured.

In some embodiments of the present disclosure, as shown in FIG. 8, the simulation unit 30 includes: a ring oscillation path 31 and a compensation simulation unit 32. The ring oscillation path 31 is arranged to simulate the first physical delay. The at least one parameter to be measured includes the number of oscillation periods corresponding to the ring oscillation path 31. The compensation simulation unit 32 is arranged to receive at least one compensation signal Sc<1>˜Sc<n> from a compensation controller, and simulate the compensation delay in response to the at least one compensation signal Sc<1>—Sc<n>.

In the embodiments of the present disclosure, in conjunction with FIG. 7 and FIG. 8, the operation control unit 41 may control the ring oscillation path 31 to start oscillation in response to the start signal OSC_1. After the ring oscillation path 31 starts oscillation, the counter unit 40 may count the number of oscillation periods of the ring oscillation path 31 and register the number of oscillation periods in the register unit 42. Further, the operation control unit 41 may control the ring oscillation path 31 to stop oscillation in response to the stop signal OSC_2. The register unit 42 may register the number of oscillation periods finally obtained for calculating the delay amount of the delay to be measured. Here, the delay to be measured includes the physical delay of the ring oscillation path 31 and the compensation delay simulated by the compensation simulation unit 32.

In some embodiments of the present disclosure, referring to FIG. 8, a number of gate level circuits included in the ring oscillation path 31 is equal to a number of gate level circuits included in the main path of the first signal path.

In the embodiments of the present disclosure, referring to FIG. 8, the ring oscillation path 31 includes a plurality of gate level circuits 310, and the number of gate level circuits 310 is equal to the number of gate level circuits included in the main path of the first signal path. Meanwhile, the length of route path in the ring oscillation path 31 may be equal to the length of route path of the main path in the first signal path. Since the physical delay includes a route path delay and a circuit delay, in which the route path delay is positively correlated with the length of route path in the signal path, and the circuit delay is positively correlated with the number of gate level circuits in the signal path, the ring oscillation path 31 and the main path of the first signal path have equal circuit delays and equal route path delays. Therefore, the ring oscillation path 31 may have the same physical delay as the main path in the first signal path.

In some embodiments of the present disclosure, referring to FIG. 8, the compensation simulation 32 includes at least one second load capacitor 321. A load connecting end of the at least one second load capacitor 321 is connected to any position of the ring oscillation path 31. The at least one second load capacitor 321 is arranged to receive the at least one compensation signal Sc<1>˜Sc<n> respectively, be activated by triggering of the at least one compensation signal Sc<1>˜Sc<n>, and change a capacitance of the at least one second load capacitor 321, to simulate the compensation delay.

In the embodiments of the present disclosure, referring to FIG. 8, the at least one second load capacitor 321 has a one-to-one correspondence with at least one first load capacitor in the first signal path. Each second load capacitor 321 has the same structure as a corresponding first load capacitor, and receives the same compensation signal as the corresponding first load capacitor. That is to say, each second load capacitor 321 has the structure as shown in FIG. 4 or FIG. 5. In this way, the at least one second load capacitor 321 can generate the same load delay as the at least one first load capacitor, so that the compensation delay can be simulated.

In some embodiments of the present disclosure, the first signal transmitted by the first signal path is a data strobe signal DQS and the second signal transmitted by the second signal path is a data signal DQ. In this case, as shown in FIG. 9, the ring oscillation path 31 includes a buffer 311, a phase divider 312, and a clk tree 313. That is to say, the first signal path for transmitting the data strobe signal DQS is connected to be ring, i.e., the ring oscillation path 31 is obtained. Since the ring oscillation path 31 and the main path of the first signal path have the same electrical elements, the ring oscillation path 31 can simulate the first physical delay.

Further, referring to FIG. 7, when the first signal transmitted by the first signal path is the data strobe signal DQS, the delay detection circuit 70 may be a DQS interval OSC function specified in the 5th Double Data Rate Synchronous Dynamic Random Access Memory (DDR5) specification. Correspondingly, the operation control unit 41 may be a data strobe signal oscillation timer (DQS OSC timer) in the DQS interval OSC function, and the simulation unit 30 may be a data strobe signal oscillation repeater (DQS OSC REP) in the DQS interval OSC function. The DQS OSC timer receives a signal ZQ_OSC_START and a signal ZQ_OSC_STOP, and further, the DQS OSC timer may control the DQS OSC REP to start oscillating in response to the signal ZQ_OSC_START, and control the DQS OSC REP to stop oscillating in response to the signal ZQ_OSC_STOP.

In addition, when a signal transmitter transmits the data strobe signal DQS and the data signal DQ, a certain relative delay is imposed to the transmission time of the two signals according to TDQS2DQ, that is, a mismatch delay is imposed between the data strobe signal DQS and the data signal DQ. Referring to FIG. 7, an external computing device may obtain the number of oscillation periods in the register unit 42, calculate the delay amount of the delay to be measured (i.e., the delay amount of the first delay of the first signal path), and transmit the delay amount of the first delay to the signal transmitter. The signal transmitter may adjust the mismatch delay according to the delay amount of the first delay, so that the timing of the data strobe signal DQS and the data signal DQ can be matched.

It is to be understood that by simulating the first delay, the delay amount of the first delay is determined, and the delay amount of the first delay is fed back to the signal transmitter, so that the signal transmitter can adjust the mismatch delay to make the timing match. Meanwhile, since the first delay includes the first physical delay and the compensation delay, the compensation delay can compensate for the change of the mismatch delay due to the influence of the PVT condition, so that the mismatch delay is controlled within a certain range, thereby ensuring the effective control of the timing.

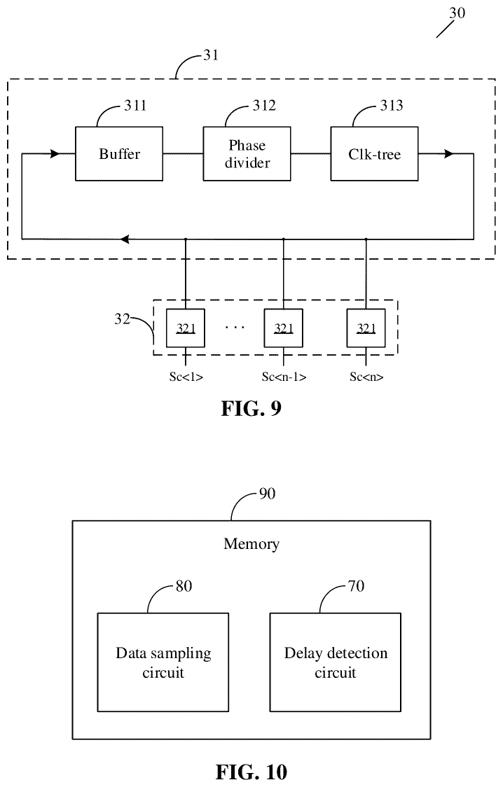

FIG. 10 is an optional schematic structure diagram of a memory provided by an embodiment of the present disclosure. As shown in FIG. 10, the memory 90 includes a data sampling circuit 80 and a delay detection circuit 70.

In some embodiments of the present disclosure, referring to FIG. 10, the memory 90 is a dynamic random access memory (DRAM).

In some embodiments of the present disclosure, referring to FIG. 10, the DRAM (i.e., the memory 90) conforms to the DDR5 memory specification.

It should be noted that in the present disclosure, terms “include” and “contain” or any other variation thereof are intended to cover nonexclusive inclusions, so that a process, method, object or device including a series of elements not only includes those elements but also includes other elements which are not clearly listed or further includes elements intrinsic to the process, the method, the object or the device. Under the condition of no more limitations, an element defined by the statement “including a/an” does not exclude existence of the same other elements in a process, method, object or device including the element.

The sequence numbers of the embodiments of the disclosure are adopted not to represent superiority-inferiority of the embodiments but only for description. The methods disclosed in some method embodiments provided in the disclosure may be freely combined without conflicts to obtain new method embodiments. The features disclosed in some product embodiments provided in the disclosure may be freely combined without conflicts to obtain new product embodiments. The features disclosed in some method or device embodiments provided in the disclosure may be freely combined without conflicts to obtain new method embodiments or device embodiments.

The above is only the specific implementation of the disclosure and not intended to limit the scope of protection of the disclosure. Any variations or replacements apparent to those skilled in the art within the technical scope disclosed by the disclosure shall fall within the scope of protection of the disclosure. Therefore, the scope of protection of the disclosure shall be subject to the scope of protection of the claims.

The embodiments of the present disclosure provide a data sampling circuit, a delay detection circuit and a memory. The data sampling circuit includes a first signal path and a second signal path. The first signal path is arranged to receive a first signal, process and transmit the first signal. The first signal path has a first delay including a first physical delay and a compensation delay. The second signal path is arranged to receive a second signal, receive processed first signal from the first signal path, and sample the second signal according to the processed first signal. Thus, when the first physical delay changes due to the influence of the PVT condition, the compensation delay provides a corresponding compensation to reduce the change of the first delay caused due to the influence of the PVT condition. Therefore, the relative delay between the first signal and the second signal can be kept stable, thereby avoid the sampling failure.

What is claimed is:

1. A data sampling circuit, comprising:
a first signal path, arranged to receive a first signal, process and transmit the first signal, the first signal path having a first delay comprising a first physical delay and a compensation delay; and
a second signal path, arranged to receive a second signal, receive processed first signal from the first signal path, and sample the second signal according to the processed first signal.

2. The data sampling circuit of claim 1, wherein the first signal path comprises:
a main path, arranged to process and transmit the first signal, the main path having the first physical delay; and
a compensation unit, coupled to the main path and arranged to receive at least one compensation signal from a compensation controller and generate the compensation delay in response to the at least one compensation signal, wherein the at least one compensation signal is obtained according to at least one of a process angle, a voltage condition, or a temperature condition.

3. The data sampling circuit of claim 2, wherein the compensation controller comprises, a temperature sensor, and the at least one compensation signal comprises at least one temperature compensation signal; and
the at least one temperature compensation signal is obtained by the temperature sensor according to the temperature condition.

4. The data sampling circuit of claim 2, wherein the compensation unit comprises: at least one first load capacitor; wherein
a load connecting end of the at least one first load capacitor is connected to any position of the main path; and
the at least one first load capacitor is arranged to receive the at least one compensation signal respectively, be activated by triggering of the at least one compensation signal and change a capacitance of the at least one first load capacitor, to generate the compensation delay.

5. The data sampling circuit of claim 4, wherein each first load capacitor of the at least one first load capacitor comprises:
an input subunit, arranged to receive one compensation signal of the at least one compensation signal and generate two control signals based on the compensation signal; and
a capacitor subunit, connected to the input subunit and arranged to be activated by triggering of the two control signals, and change the capacitance of the first load capacitor.

6. The data sampling circuit of claim 5, wherein the input subunit comprises:
a first inverter, arranged to receive the compensation signal and output a first control signal of the two control signals; and
a second inverter, having an input end connected to an output end of the first inverter, arranged to output a second control signal of the two control signals.

7. The data sampling circuit of claim 6, wherein the capacitor subunit comprises:
a first metal oxide semiconductor (MOS) transistor, having a source and a drain both connected to the output end of the first inverter; and
a second MOS transistor, having a source and a drain both connected to an output end of the second inverter, a gate of the second MOS transistor and a gate of the first MOS transistor being connected and both serving as the load connecting end of the first load capacitor, and a type of the second MOS transistor being opposite to that of the first MOS transistor.

8. The data sampling circuit of claim 1, wherein the first signal is a data strobe signal and the second signal is a data signal.

9. A delay detection circuit, comprising:
a simulation unit, arranged to simulate the first delay of the first signal path of claim 1 and generate a delay to be measured, the first delay comprising a first physical delay and a compensation delay; and
a counter unit, coupled to the simulation unit, arranged to count at least one parameter to be measured corresponding to the simulation unit to calculate a delay amount of the delay to be measured.

10. The delay detection circuit of claim 9, wherein the simulation unit comprises:
an ring oscillation path, arranged to simulate the first physical delay, the at least one parameter to be measured comprising a number of oscillation periods corresponding to the ring oscillation path; and
a compensation simulation unit, arranged to receive at least one compensation signal from a compensation controller, and simulate the compensation delay in response to the at least one compensation signal.

11. The delay detection circuit of claim 10, wherein a number of gate level circuits comprised in the ring oscillation path is equal to a number of gate level circuits comprised in a main path of the first signal path.

12. The delay detection circuit of claim 10, wherein the compensation simulation unit comprises: at least one second load capacitor; wherein
a load connecting end of the at least one second load capacitor is connected to any position of the ring oscillation path; and
the at least one second load capacitor is arranged to receive the at least one compensation signal respectively, be activated by triggering of the at least one compensation signal and change a capacitance of the at least one second load capacitor, to simulate the compensation delay.

13. The delay detection circuit of claim 12, wherein:
the at least one second load capacitor has a one-to-one correspondence with at least one first load capacitor in the first signal path; and
each second load capacitor of the at least one second load has the same structure as a corresponding first load capacitor, and receives the same compensation signal as the corresponding first load capacitor.

14. The delay detection circuit of claim 12, further comprising:
an operation control unit, coupled to the simulation unit, arranged to receive a start signal and a stop signal, and control an operation time of the simulation unit according to the start signal and the stop signal; and
a register unit, coupled to the counter unit and arranged to register the at least one parameter to be measured.

15. A memory, comprising at least one of a data sampling circuit, or a delay detection circuit, wherein the data sampling circuit comprises:
a first signal path, arranged to receive a first signal, process and transmit the first signal, the first signal path having a first delay comprising a first physical delay and a compensation delay; and
a second signal path, arranged to receive a second signal, receive processed first signal from the first signal path, and sample the second signal according to the processed first signal; and
the delay detection circuit comprises:
a simulation unit, arranged to simulate the first delay of the first signal path and generate a delay to be measured; and
a counter unit, coupled to the simulation unit, arranged to count at least one parameter to be measured corresponding to the simulation unit to calculate a delay amount of the delay to be measured.

16. The memory of claim 15, wherein the memory is a dynamic random access memory (DRAM).

17. The memory of claim 16, wherein the DRAM conforms to a 5th double data rate synchronous dynamic random access memory (DDR5) memory specification.
